(19) United States
(12) Patent Application Publication
(10) Pub. No.: US 2013/0146445 A1
(43) Pub. Date: Jun. 13, 2013

(54) PROCESS FOR COATING A SUBSTRATE BY MEANS OF AN ARC

(71) Applicant: Oliver Kayser, Monschau (DE)

(72) Inventor: Oliver Kayser, Monschau (DE)

(73) Assignees: HOEDTKE GMBH & CO. KG, Pinneberg (DE); DREISTEGEN GMBH, Monschau (DE)

(21) Appl. No.: 13/808,577

(22) PCT Filed: Jul. 12, 2011
(86) PCT No.: PCT/EP2011/061873

§ 371 Date: Feb. 13, 2013

(30) Foreign Application Priority Data
Jul. 12, 2010 (DE) 10 2010 036 332.4

(51) Int. Cl. C23C 14/32

(52) U.S. Cl. CPC C23C 14/325
USPC 204/192.38; 204/298.41

(57) ABSTRACT

The invention relates to a process and an evaporator for coating a substrate by means of an arc in a vacuum chamber (10) in the case of low-pressure arc evaporation, wherein the vacuum chamber (10) has at least one evaporator, which comprises a target material (20), reactive gas supply lines (53, 54) for supplying reactive gas, and a vacuum pump, wherein the evaporator comprising the target material (20) serves as the cathode and the inner wall (36) of the vacuum chamber (10) serves as the anode between which the arc is generated. According to the invention, high-melting point metal is used as the target material (20) for catalysis, and the pressure in the vacuum chamber (20) during coating is at least 0.5 Pa, in particular at least 3 Pa, preferably 5 Pa. A layer of catalytically active metal having a high oxygen content is formed on the substrate.

This application claims the benefit and priority of and to PCT/EP2011/061873, international application filing date Jul. 12, 2011, which claims the benefit and priority of and to: German patent application no. 10 2010 036 332.4, filed Jul. 12, 2010. PCT/EP2011/061873, international application filing date July 12, 2011, which claims the benefit and priority of and to: German patent application no. 10 2010 036 332.4, filed Jul. 12, 2010 are incorporated herein by reference hereto in their entireties.

The invention relates to a process for coating a substrate by means of an arc as well as to an evaporator of a vacuum chamber for performing the process for coating a substrate by means of an arc in a vacuum chamber at low pressure.

Processes for coating a substrate by means of an arc in a vacuum chamber at low pressure—arc evaporation—have been known for a long time. Arc evaporation or arc-PVD is an ion plating PVD process. In this process, an arc is struck between the chamber and the target material which is at a negative potential, said arc causing the target material to melt and evaporate. The target material thus constitutes the cathode. In this process, the molten and evaporated target material reacts with reactive gas that is introduced into the chamber and then deposits on the substrate, i.e. the workpiece to be coated in the vacuum chamber. During arc evaporation, a major portion of the evaporated material becomes ionized. The material vapor then spreads starting from the target material. As a negative potential is additionally applied to the substrate—negative bias voltage—the ionized material vapor is first accelerated towards the substrate. The material vapor then condenses at the substrate surface. In view of the high ionization shares, a vast amount of kinetic energy can be introduced into the material vapor by means of respective stresses on the substrate and on the target. This allows a more or less pronounced stress effect to be achieved in the substrate. Amongst others, this is used for influencing the properties of the deposited layer such as layer adhesion, density, composition and the like.

Such layers are required as wear protection for generating anti-bonding surfaces or for corrosion-proofing tools and components. Processes for coating by means of an arc are basically known from the coating of cutting tools. The coatings thus obtained are intended to make the underlying highly hardened carrier materials wear-resistant. Arc evaporation is performed in vacuum chambers at a reduced total pressure; cf. WO 2009/110830 A1. The chambers used for this purpose are generally small in dimension for which reason they are usually unsuited for coating large components. As the deposition occurs through individual round sources provided in the chamber wall, the arc evaporation process is highly scalable and thus has the ideal prerequisites for use in large vacuum chambers.

In most cases, it is considered advantageous to achieve an as effective as possible combination of the metal vapor and the reactive gas. Otherwise local areas of pure metal, so called droplets, will form in the deposited layers. This will result in a roughened surface, in less dense and thus less corrosion-resistant layers as well as in a change in the electrical and surface chemical properties of the layers.

Frequently, especially combinations of high melting point metals such as Mo, Nb, W, Ta, Hf, Zr, Ru and Ir exhibit interesting mechanical, electrical and surface chemical properties. The deposition of these metals by means of arc evaporation requires a relatively high arc current, i.e. above 100 amps, and high arc voltages of frequently over 20 V.

Such coatings are also required for electrodes, for example. So far, however, one has refrained from producing electrodes that are intended for use especially in electrolysis, above all in chlor-alkali electrolysis, by means of arc evaporation. Such catalytically active coatings consist of a high melting point metal having a high oxygen content. If such layers were produced by means of arc evaporation, this would require very high arc currents, which would in turn result in high vaporization rates and thus an insufficient reaction with the reactive gas. Catalytically active layers for electrodes are difficult to implement technically and economically by means of arc evaporation. For this reason, these coatings have so far been generated using known spraying or immersion methods or mechanical application methods.

As a general rule, processes for coating a substrate by means of an arc are performed in a vacuum chamber at low pressure. For this purpose, the vacuum chamber has at least one evaporator which comprises the target material. Moreover, gas supply means for supplying reactive gas and a vacuum pump for generating a low pressure are provided. The evaporator comprising the target material serves as the cathode and the inner wall of the vacuum chamber serves as the anode. The arc is then generated between the target material and the inner wall of the vacuum chamber. The pressure prevailing in the vacuum chamber is low pressure, i.e. usually a pressure of between 0.05 Pa and 2.00 Pa.

It is the object of the present invention to further develop a process for coating a substrate using an arc in a vacuum chamber in such a manner that—regarding mixture—as effective as possible combinations are obtained of the high melting point metals on the one hand and components of the supplied reactive gases on the other.

The invention is based on the insight that the mixing of the layer-forming metal and the reactive gas can be improved by increasing pressure.

Catalytically active coatings are a crucial prerequisite for the economical chlor-alkali electrolysis for large-scale chlorine and sodium hydroxide solution production. In practice, the overvoltage can be reduced in particular by means of ruthenium oxide coatings. These coatings have so far been applied mechanically in the form of a liquid film which is subsequently cured. This process has the advantage that it does not require much equipment. The thickness of the applied film is closely related to the viscosity and surface energy of the applied liquid on the one side where the mechanical application is performed. The subsequent thermal curing step serves to remove volatile bonding agents and to cause the coating to solidify.

Such processes involve the danger of the surface becoming micro-embrittled. In order to obtain a high adhesion strength, it is additionally required that the surface be coated in a metallically bright state. Especially organic impurities that are almost invisible will result in dissatisfactory layer adhesion. This insufficient bonding to the basic material may become noticeable immediately or only after some time in process operation. Owing to its mechanical nature, this type of application is easy but harbors certain risks with regard to the mechanical properties, the layer density and the adhesion of the coating. However, all these factors contribute considerably to the function and the durability of the coating. For this reason, a process is required which ensures the deposition of layers having the following properties:
high adhesion strength
precisely adjustable composition
precisely maintainable layer thickness
easy control and documentation of the process

According to the invention, a high melting point metal is used as the target material for electrically active surfaces and/or for catalysis, and the pressure in the vacuum chamber during coating is at least 0.5 Pa, in particular at least 3 Pa and preferably at least 5 Pa. A layer of electrically active metal having a high oxygen content and/or of a catalytically active metal having a high oxygen content is thus formed on the substrate. In view of the pressure range, the collision rate between the layer-forming metal and the reactive gas is sufficiently increased and only a small arc current is required. This in turn results in a lower vaporization rate and thus in further enhanced mixing and reaction of the layer-forming metal with the reactive gas. Improved saturation of the layer-forming metal vapor with the reactive gas is achieved through deposition at this relatively high total pressure in the vacuum chamber. This results in a high likelihood of collision of vaporized layer-forming metal and reactive gas. As a further result, the pure metal content in the layer may advantageously be reduced further. This saves further material costs, in addition to the considerably lower arc current.

Electrically active surfaces are required for catalysis but also for the low-loss current supply in batteries, i.e. low-loss transitions from the electrolyte to the electrode. In general, the term electrically active surface refers to surfaces having defined properties regarding electrical resistance and electrolytic overvoltage for electrical applications.

In accordance with a preferred embodiment of the process, pure oxygen —O₂—or a gas having a high oxygen content is used as the reactive gas.

For use as the high melting point metal, for example for electrodes, ruthenium, iridium, titanium, platinum or mixtures thereof have proved useful. Consequently, a high melting point metal in the form of ruthenium, iridium, titanium, platinum or mixtures thereof is used as the target material.

In accordance with a preferred embodiment of the invention, the arc current is at least 65 amps, preferably 75 amps. Thorough mixing of the layer-forming material with the reactive gas is thus ensured in a simple way as the vaporization rate decreases. As the vaporization rate decreases, the likelihood of collisions of vaporized layer-forming material and reactive gas increases.

In order to ensure an economic realization of the process, the arc current is not higher than 100 amps.

So far it has been customary to supply the reactive gas to the vacuum chamber in such a way that the vacuum chamber was randomly flooded with reactive gas. However, in order to achieve improved saturation of the layer-forming metal vapor with reactive gas, according to yet another embodiment of the process of the invention, the reactive gas is supplied to the target material directly at the evaporator in the course of the coating process. Preferably, the reactive gas is supplied to the target material in an annular manner and uniformly distributed around the ring.

According to yet another embodiment of the process of the invention, a negative voltage is applied to the substrate, i.e. the workpiece to be coated. In view of the high level of ionization in arc evaporation, this negative voltage applied to the substrate causes the layer-forming particles to be accelerated towards the substrate which results in clearly improved layer adhesion. For this reason, no adhesion promoting layers are required during coating.

According to a preferred embodiment of the process of the invention, the process is used for coating electrodes which are preferably used for electrolysis, above all for chlor-alkali electrolysis.

The catalytically active layers are characterized by a high oxygen content. It is generally known that oxygen in the chamber is associated with low adhesion strength of the layers. Oxygen-containing coatings have already been known from the deposition of chromium and aluminum oxide. However, the present process ensures sufficient adhesion strength by deposition at high temperatures above 400° C. to 500° C. Here use is made of the fact that high deposition temperatures as a rule always result in improved bonding. However, the deposition of large-area catalytic coatings at homogeneously high temperatures requires a considerable amount of equipment. Additional problems are caused by stresses resulting from the different degrees of thermal expansion of the substrate and the layer. Given the typical dimensions of 1.2×2.7 m, these stresses will add up and ultimately cause the applied coating to break off. Unlike with cutting tools of small dimensions, high temperature deposition does not provide a solution here.

The adhesion strength of PVD layers is considerably impaired by impurities and natural oxides. In addition, impurities may have the effect of an electrical barrier layer. Optimum cleaning can be achieved by blasting with hard corundum. At least the natural oxidation after the cleaning of the surface and before depositing the coating layer cannot be avoided. Thus the mechanical application of catalytic coatings involves the risk of barrier layers being formed or of insufficient bonding with the basic material. In the arc evaporation process described herein, the decomposition of the natural oxide is obtained by glowing in a mixture of argon and hydrogen. In this case, the argon has a purely mechanical atomizing function, whereas the hydrogen serves for the chemical reduction of the oxide film. The arc evaporation process additionally allows a high ionization level of the layer-forming species of more than 90% to be obtained. Thus almost all the layer-forming vapor particles can be accelerated towards the substrate surface and shot into the substrate lattice. The combination of mechanical cleaning, in particular corundum blasting, physical action (argon) and chemical etching (hydrogen) at a high ionization level of the layer-forming species (arc evaporation) by means of the above mentioned measures yields the surprising result for the expert in the field that oxidic layers can be deposited on large areas—scalable arc evaporation—in a reproducible and reliable manner at low temperatures, in particular 200° C.

Usually the reactive gas, e.g. O₂, is introduced into the peripheral zone of the vacuum chamber by means of an injection lance. However, this results in a not insubstantial saturation of the cathodic donor material with reactive gas. However, in order to still obtain a calm burning behavior, the evaporator will have to be operated at a current that is increased by approx. 30%. This effect makes it difficult to design evaporators having small dimensions. What makes the use of small evaporators particularly attractive is that small donor bodies can be obtained more easily. As an alternative, a high degree of saturation with reactive gas may be achieved by directly supplying it through annular nozzles disposed around the evaporator, as will be explained in more detail below. The high reactive gas content allows the arc current to be reduced, thus also reducing the cooling requirements. Also, the material to be vaporized may be completely saturated with reactive gas.

Arc evaporation is thus characterized by a high degree of flexibility in the layer composition. The composition of the layers can thus be changed from metallic to oxidic with increasing layer thickness by increasing the amount of reactive gas—oxygen—that is introduced. Such transitions may improve the functionality of the catalytic layers or may also be used as a wear protection indicator.

According to yet another feature of the invention, its object is accomplished by an evaporator of a vacuum chamber for performing a process for coating a substrate by means of an arc in a vacuum chamber at low pressure—arc evaporation—in that the reactive gas supply means is annularly disposed around the target material and exhibits regularly spaced gas outlet apertures. This also ensures thorough mixing of layer-forming material and reactive gas. This is also guaranteed despite the high vaporization rates in the arc and results in a very high saturation of the vaporized electrically active and/or catalytically active material of the target material.

In particular the reactive gas supply means is axially and radially spaced from the target material in such a way that it will not interfere with the arc during arc evaporation.

The distance and the annular shape must be chosen so as to be large enough to avoid short circuits, to prevent the reactive gas supply means from overheating and to prevent evaporator shutdown.

The reactive gas outlet apertures especially all have the same cross-section. The annular shape of the reactive gas supply means shifts the oxide formation from the vapor phase to the cathode surface, i.e. the surface of the target material. In particular, a finer distribution of the arcs on the cathode surface is thus obtained. This in turn allows the arc current to be reduced. A reduction of the arc current results in a reduction of the cathode surface temperature. This allows lower vaporization rates of the layer-forming material to be set. Lower vaporization rates in turn allow an improved reaction between the layer-forming metal and the reactive gas.

Further advantages, features and possible applications of the present invention may be gathered from the description which follows, in combination with the embodiments illustrated in the drawings. Throughout the description, the claims and the drawings, the same terms and reference numerals have been used as indicated in the list of reference numerals below. In the drawings,

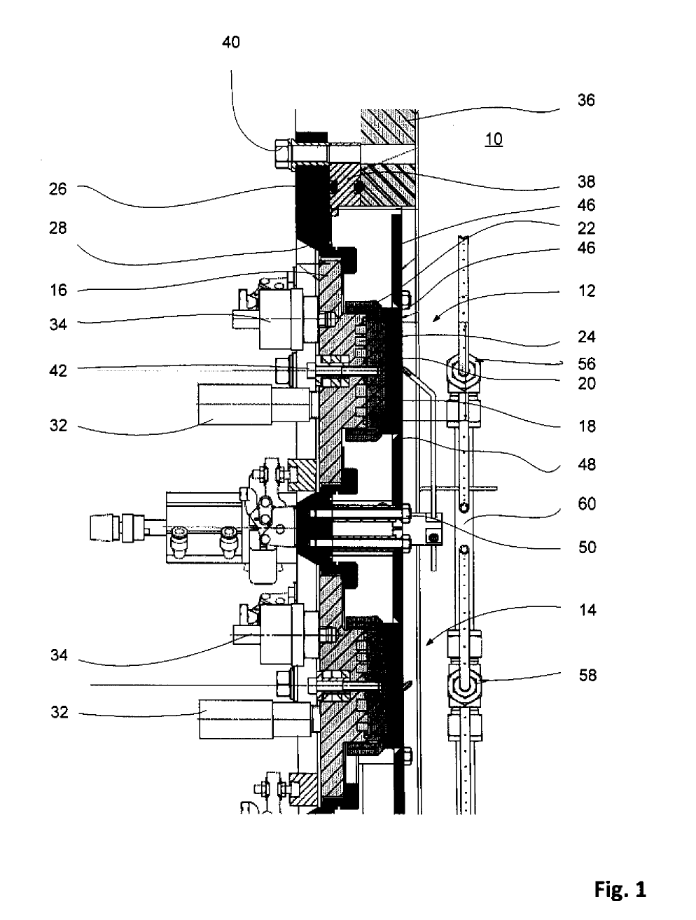

FIG. 1 is a cross-sectional view of two evaporators according to the invention which are mounted next to each other in a vacuum chamber;

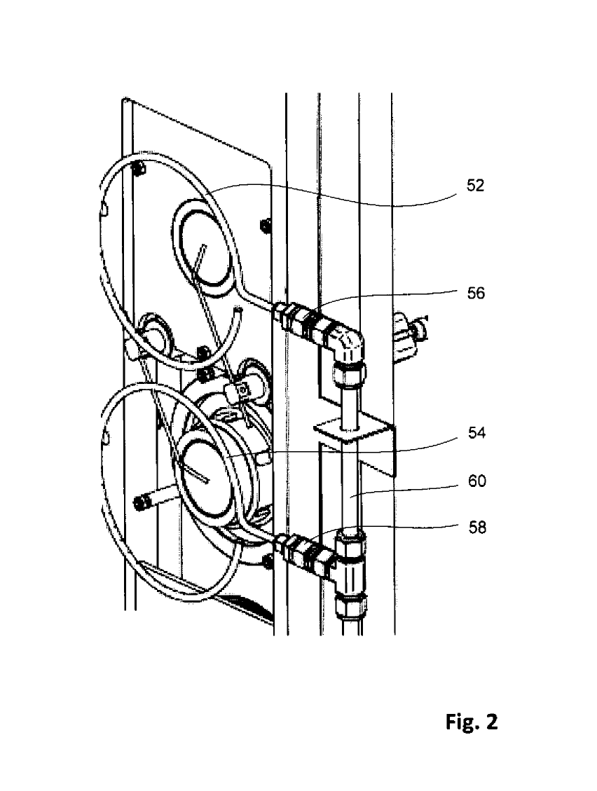

FIG. 2 a perspective angular view of the two evaporators of FIG. 1;

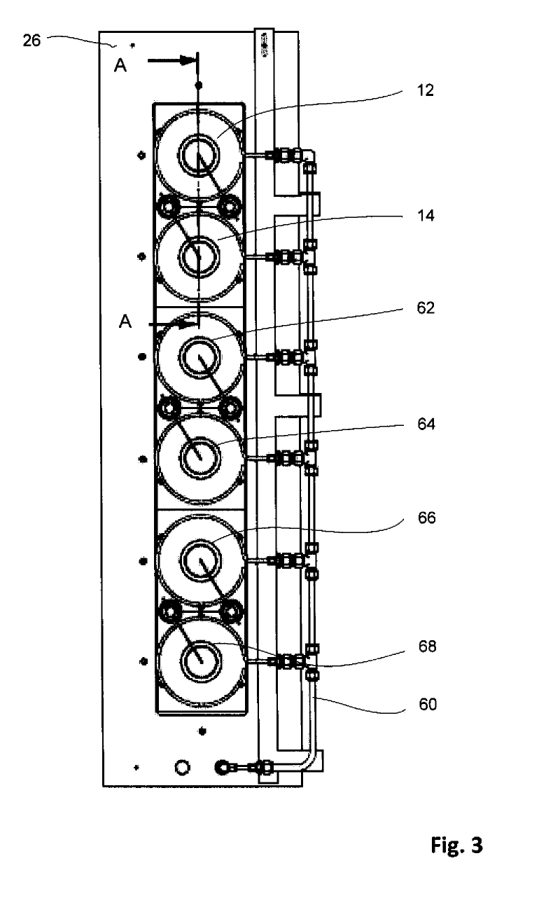

FIG. 3 a top view of the support with the evaporators, and

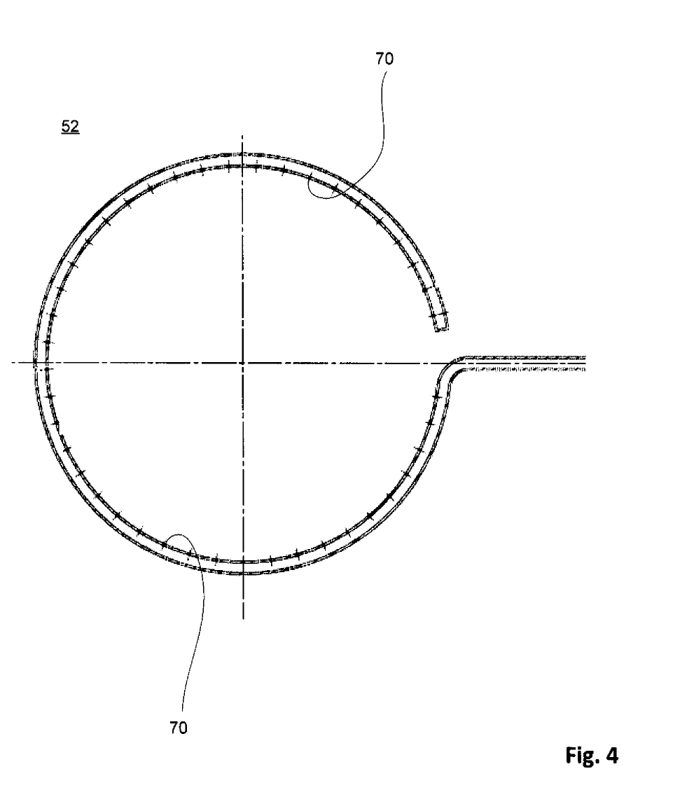

FIG. 4 a top view of the annular reactive gas supply means.

FIG. 1 shows a cross-sectional view of two evaporators 12, 14 mounted next to each other in a vacuum chamber 10 for performing the process of coating a substrate by means of an arc in a vacuum chamber at low pressure—arc evaporation. The section lines, i.e. lines A-A, can been seen in FIG. 3. The vacuum chamber 10 may include a plurality of evaporators 12, 14. Both evaporators 12, 14 are of equivalent and corresponding design each.

Each evaporator 12, 14 has a basic body 16 on which a target support 18 with target material 20 is held by means of a quick-release fastener 22. Provided in the basic body 16 are cooling ducts 24 for cooling the target support 18 and thus the target material 20 during arc evaporation.

The evaporators 12, 14 are accommodated in an evaporator support 26 and firmly connected to it. For this purpose, the evaporator support 26 exhibits recesses 28 conforming and adapted to the evaporators 12, 14 and evaporator holding fixtures 30 that are connected to the evaporator support 26 on the one side as well as the associated evaporator 12, 14 on the other side.

The cooling ducts 24 extend almost across the entire side of the target support 18 facing the basic body 16 and are connected to a cooling connection 32.

The basic body 16 is connected to a current supply 34, thus allowing a negative potential to be applied to the basic body 16, the target support 18 and the target material 20 so that the target material 20 functions as a cathode.

The evaporator support 26 is screwed to a chamber wall 36 of the vacuum chamber 10, with insulating means 38 being provided between the evaporator support 26 and the chamber wall 36. Moreover, the screw connection 40 is insulated from the evaporator support 26. Consequently, the evaporator support 26 is completely insulated from the chamber wall 36 of the vacuum chamber 10.

Besides the quick-release fastener 22, the target support 18 comprising the target material 20 is also connected to the basic body 16 via another screw connection 42. Mounted on the quick-release fastener 22 as well as around the target material 20 is a ring 44 which consists of boron nitride.

The ring 44 and the target material 20 define a common plane 46. Disposed in this plane 46 is the surface of a shield panel 48 which encompasses the evaporator 12, 14 in the area of the target material 20. The shield panel 48 is connected to the evaporator support 26 via fastening means 50. Extending in parallel to the plane 46 and spaced therefrom, reactive gas supply means 52, 54 for each evaporator 12, 14 are provided. The reactive gas supply means 52, 64 are designed identically and correspondingly, see FIG. 2.

The reactive gas supply means 52, 54 are connected to a reactive gas supply line 60 via corresponding connections 56, 58.

The top view of FIG. 3 shows the evaporator support 26 with six evaporators 12, 14, 62, 64, 66, 68. Depending on the dimensions, it is also possible to arrange more or fewer evaporators 12, 14, 62, 64, 66, 68 in an evaporator support 26. It is likewise possible to design the evaporator support 26 for six evaporators 12, 14, 62, 64, 66, 68 for example, but only use four evaporators in it. In this case, the evaporators that are not required will not actually be installed but merely the recess 28 will be provided in a plate not shown here.

In a vacuum chamber 10, plural evaporator supports 26 may be mounted that have a plurality of evaporators 12, 14, 62, 64, 66, 68.

FIG. 4 shows the reactive gas supply means 52 which corresponds to the other reactive gas supply means 54 and the reactive gas supply means not bearing any reference numerals. The reactive gas supply means 52 is of annular design and includes regularly spaced reactive gas outlet apertures 70. This allows the reactive gas to be uniformly supplied adjacent to the target material 20. The reactive gas supply means 52 is disposed in parallel to the plane 46 and axially and radially spaced from the target material 20 with respect to the cylindrical form of the latter so as to prevent inference with the arc during arc evaporation.

The reactive gas outlet apertures 70 have a uniform aperture cross-section. Oxygen is supplied via the reactive gas supply means 52, 54, with a high-melting point metal, i.e. ruthenium, being used as the target material 20 for catalysis. During the coating of the substrate not shown here by means of an arc in the vacuum chamber 10, a pressure of at least 3 Pa, preferably 5 Pa, is set in the vacuum chamber 10. For this purpose controlling and regulating means are provided which suitably control the vacuum pump not shown here. The running current is at least 65 amps, preferably 75 amps, and thus clearly below 100 amps.

A negative bias voltage is applied to the substrate not shown here, in order to improve layer adhesion.

The process of the invention and the evaporator of the invention are preferably used for producing electrodes for electrolysis, above all for chlor-alkali electrolysis, in which the electrodes include a layer of an electrically active and at the same time catalytically active metal having a high oxygen content.

Example of the procedural steps according to the invention for a catalytic coating:
1. Alkaline cleaning of the support material.
2. Roughening the substrate by corundum blasting using standard corundum 120 at 6,000 Pa.
3. Further cleaning of the substrate in an ultrasound environment for removal of blasting material.
4. Charging the substrate.
5. Evacuating the vacuum chamber to 0.1 Pa.
6. Heating the substrate to 200° C.
7. Glowing the substrate in an Ar/H2 mixture at 5 Pa for approx. 15 min.
8. Coating the substrate with catalytic material at 200° C. and between 3 and 5 Pa.

### LIST OF REFERENCE NUMERALS

10 vacuum chamber
12 top evaporator
14 bottom evaporator
16 basic body
18 target support
20 target material
22 quick-release fastener
24 cooling duct
26 evaporator support
28 evaporator support recesses
30 evaporator holding fixtures
32 cooling connection
34 electrical connection
36 chamber wall
38 insulating means
40 screw connection
42 additional screw connection
44 ring
46 plane
48 shield panel
50 fastening means
52 top reactive gas supply means
54 bottom reactive gas supply means
56 top connection
58 bottom connection
60 reactive gas supply line
62 evaporator
64 evaporator
66 evaporator
68 evaporator
70 reactive gas outlet aperture

1-14. (canceled)

15. A process for coating a substrate by means of an arc in a vacuum chamber (10) at low pressure—arc evaporation—, said vacuum chamber includes at least one evaporator (12, 14, 62, 64, 66, 68), comprising the steps of:
generating an arc using said at least one evaporator (12, 14, 62, 64, 66, 68) of said vacuum chamber (10) wherein said at least one evaporator comprises a target material (20) and wherein said evaporator (12, 14, 62, 64, 66, 68) which comprises said target material (20) serves as a cathode and the inner wall (36) of said vacuum chamber (10) serves as an anode between which said arc is generated;
using reactive gas supply means (53, 54) for supplying reactive gas;
using a vacuum pump;
using a high melting point metal as said target material (20) for electrically active surfaces and/or for catalysis;
using a pressure of at least 0.5 Pa in said vacuum chamber (10) during coating;
forming a layer of electrically active metal having a high oxygen content and/or a layer of a catalytically active metal having a high oxygen content on said substrate.

16. The process of claim 15 wherein oxygen or a gas having a high oxygen content is used as the reactive gas.

17. The process of claim 15 wherein ruthenium, iridium, titanium, platinum or mixtures thereof are used as the target material (20).

18. The process of claim 15 wherein said arc generation requires an arc current of at least 65 amps.

19. The process of claim 15 wherein said arc generation requires an arc current of at least 75 amps.

20. The process of claim 15 wherein said arc generation requires an arc current and said arc current does not exceed 100 amps.

21. The process of claim 15 wherein said reactive gas is supplied to said target material (20) at said evaporator (12, 14, 62, 64, 66, 68).

22. The process of claim 18 wherein said reactive gas is supplied to said target material (20) in an annular manner.

23. The process of claim 19 wherein said reactive gas is supplied to said target material (20) in an annular manner.

24. The process of claim 15 wherein a negative bias voltage is applied to said substrate.

25. The process of claim 15 wherein electrodes are coated for use in electrolysis including chlor-alkali electrolysis.

26. The process of claim 15, further comprising the steps of:
alkaline cleaning of said substrate;
roughening of said substrate;
ultrasound cleaning of said substrate for blasting material removal;
charging said substrate;
evacuating said vacuum chamber;
heating said substrate;
glowing said substrate in an Ar/H₂ mixture; and, coating said substrate with catalytic material.

27. The process of claim 15, further comprising the steps of:
alkaline cleaning of said substrate;
roughening of said substrate by corundum blasting thereof at 6,000 Pa, said corundum being standard corundum 120;
ultrasound cleaning of said substrate for blasting material removal;
charging said substrate;
evacuating said vacuum chamber to 0.1 Pa;
heating said substrate to 200° C.;
glowing said substrate in an Ar/H₂ mixture at 5 Pa for 15 min; and, coating said substrate with catalytic material at 200° C. and 3 to 5 Pa.

28. An evaporator (12, 14, 62, 64, 66, 68) of a vacuum chamber (10) for coating a substrate by means of an arc in a vacuum chamber at low pressure—arc evaporation—comprising:
said evaporator (12, 14, 62, 64, 66, 68) comprises a target material (20);
a reactive gas supply means (52, 54) is disposed around said target material (20) in an annulus and includes regularly spaced reactive gas outlet apertures (70).

29. An evaporator as claimed in claim 28 wherein said reactive gas supply means (52, 54) is axially and radially spaced from said target material (20) at such a distance that it will not interfere with said arc during said arc evaporation process.

30. The evaporator as claimed in claim 28 wherein said reactive gas outlet apertures (70) each have the same cross-section.

31. The evaporator as claimed in claim 28 wherein said target material (20) is a high melting point metal for catalysis.

32. A process for coating a substrate by means of an arc in a vacuum chamber (10) at low pressure—arc evaporation—, said vacuum chamber includes at least one evaporator (12, 14, 62, 64, 66, 68), comprising the steps of:
generating an arc using said at least one evaporator (12, 14, 62, 64, 66, 68) of said vacuum chamber (10) wherein said at least one evaporator comprises a target material (20) and wherein said evaporator (12, 14, 62, 64, 66, 68) which comprises said target material (20) serves as a cathode and the inner wall (36) of said vacuum chamber (10) serves as an anode between which said arc is generated;
using reactive gas supply means (53, 54) for supplying reactive gas;
using a vacuum pump;
using a high melting point metal as said target material (20) for electrically active surfaces and/or for catalysis;
using a pressure of at least 3 Pa in said vacuum chamber (10) during coating;
forming a layer of electrically active metal having a high oxygen content and/or a layer of a catalytically active metal having a high oxygen content on said substrate.

33. A process for coating a substrate by means of an arc in a vacuum chamber (10) at low pressure—arc evaporation—, said vacuum chamber includes at least one evaporator (12, 14, 62, 64, 66, 68), comprising the steps of:
generating an arc using said at least one evaporator (12, 14, 62, 64, 66, 68) of said vacuum chamber (10) wherein said at least one evaporator comprises a target material (20) and wherein said evaporator (12, 14, 62, 64, 66, 68) which comprises said target material (20) serves as a cathode and the inner wall (36) of said vacuum chamber (10) serves as an anode between which said arc is generated;
using reactive gas supply means (53, 54) for supplying reactive gas;
using a vacuum pump;
using a high melting point metal as said target material (20) for electrically active surfaces and/or for catalysis;
using a pressure of at least 5 Pa in said vacuum chamber (10) during coating;
forming a layer of electrically active metal having a high oxygen content and/or a layer of a catalytically active metal having a high oxygen content on said substrate.
